(19) United States
(12) Patent Application Publication
(10) Pub. No.: US 2014/0085853 A1
(43) Pub. Date: Mar. 27, 2014

(54) DISPLAY APPARATUS

(71) Applicants: Yi-Shian Chiou, Hsinchu City (TW); Chong-Yang Fang, Taichung City (TW); Wen-Chun Wang, Taichung City (TW); Wei-Chou Chen, Hsinchu City (TW); Hen-Ta Kang, Taichung City (TW); Tsung-Yen Hsieh, Taichung City (TW)

(72) Inventors: Yi-Shian Chiou, Hsinchu City (TW); Chong-Yang Fang, Taichung City (TW); Wen-Chun Wang, Taichung City (TW); Wei-Chou Chen, Hsinchu City (TW); Hen-Ta Kang, Taichung City (TW); Tsung-Yen Hsieh, Taichung City (TW)

(73) Assignees: WINTEK CORPORATION, Taichung City (TW); DONGGUAN MASSTOP LIQUID CRYSTAL DISPLAY CO., LTD., Guangdong Province (CN)

(21) Appl. No.: 14/027,161

(22) Filed: Sep. 14, 2013

(30) Foreign Application Priority Data
Sep. 24, 2012 (TW) 101134920

(51) Int. Cl. H05K 7/02

(52) U.S. Cl. CPC H05K 7/02
USPC 361/783

(57) ABSTRACT

A display apparatus including a display and a waveguide plate is provided. The display panel includes multiple rows of display units and multiple rows of solar cell units. The display units and the solar cell units are substantially parallel to a first direction and alternately arranged along a second direction perpendicular to the first direction. The waveguide plate is disposed at one side of the display panel. A first side of the waveguide plate adjacent to the display panel includes multiple microstructures. First and second structure surfaces of each microstructure respectively correspond to one row of the display units and one row of the solar cell units. When the display apparatus is disposed such that the second direction is perpendicular to a ground surface, an inclination of the first structure surface makes a thickness of the waveguide plate gradually decrease along an upward direction from the ground surface.

### CROSS-REFERENCE TO RELATED APPLICATION

This application claims the priority benefit of Taiwan application serial no. 101134920, filed on Sep. 24, 2012. The entirety of the above-mentioned patent application is hereby incorporated by reference herein and made a part of this specification.

### BACKGROUND OF THE INVENTION

1. Field of the Invention

The present invention relates to display apparatuses, and more particularly, to a display apparatus including a solar cell.

2. Description of Related Art

Display apparatus that are disposed outdoor, such as outdoor billboards or advertising boards, need to satisfy the requirements of sufficient illumination, low cost and keeping power on for a long time. In order to provide the desired driving voltage for the display apparatus, in addition to display units for displaying purposes, the display apparatus can also include solar cells to directly convert the solar light into the desired driving power. Therefore, it is an important subject to increase the photovoltaic conversion performance of the solar cells of the display apparatus.

### SUMMARY OF THE INVENTION

Accordingly, the present invention is directed to a display apparatus which includes solar cell units, the solar cell units having high photovoltaic conversion performance thus facilitating reducing the power consumption.

The present invention provides a display apparatus including a display and a waveguide plate. The display panel includes multiple rows of display units and multiple rows of solar cell units. The display units and the solar cell units are substantially parallel to a first direction and alternately arranged along a second direction perpendicular to the first direction. The waveguide plate is disposed at one side of the display panel. A first side of the waveguide plate adjacent to the display panel includes a plurality of microstructures. Each microstructure substantially includes a first structure surface and a second structure surface. The first structure surface and the second structure surface of each microstructure respectively correspond to one row of the display units and one row of the solar cell units. When the display apparatus is disposed such that the second direction is perpendicular to a ground surface, an inclination of the first structure surface makes a thickness of the waveguide plate gradually decrease along an upward direction from the ground surface.

In one embodiment, the display units may include light emitting diode units, electrophoretic display units, electro-wetting display units, liquid crystal display units, and organic light emitting display units.

In one embodiment, the display units and the solar cell units are substantially coplanar.

In one embodiment, an angle between the first structure surface and the second structure surface of each microstructure is substantially less than 180 degrees.

In one embodiment, the second structure surface of each microstructure is substantially parallel to a display surface of the corresponding display unit.

In one embodiment, the first structure surface and the second structure surface of each microstructure incline in opposite directions with respect to a boundary between the first structure surface and the second structure surface.

In one embodiment, the first structure surface and the second structure surface of each microstructure are symmetrical with each other with respect to a boundary between the first structure surface and the second structure surface.

In one embodiment, the second structure surface of each microstructure is a rough surface.

In one embodiment, the second structure surface of each microstructure is a curved surface.

In one embodiment, the first structure surfaces and the second structure surfaces of the microstructures are alternately arranged along the second direction.

In one embodiment, when the display apparatus is used at a 23 degrees latitude site, the angle between the first structure surface of each microstructure and the second direction is 5 degrees.

In one embodiment, when the display apparatus is used at a 30 degrees latitude site, the angle between the first structure surface of each microstructure and the second direction is 7 degrees.

In one embodiment, the display apparatus may further include an optical adhesive disposed between the second structure surface of each microstructure and one corresponding row of the solar cell units.

In one embodiment, a refractive index of the optical adhesive is substantially equal to a refractive index of the waveguide plate.

In one embodiment, a material of the waveguide plate comprises polymethylmethacrylate (PMMA).

In one embodiment, a second side of the waveguide plate includes a flat surface, and the first side and the second side are opposite to each other.

In view of the foregoing, in the display apparatus according to the embodiments of the present invention, the display panel includes strip-distributed display units and strip-distributed solar cell units, and the solar cell units and the display units are alternately arranged. In addition, in the display apparatus, the waveguide plate is disposed in front of the display panel, which reduces the amount of external light directly irradiating onto the display units, such as the light emitting diodes and even increases the amount of external light irradiating onto the solar cell units. As such, the lifetime of the light emitting diodes in the display apparatus can be prolonged and the photovoltaic conversion performance of the solar cell units can be enhanced.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

FIG. 1 is a top view of a display apparatus according to one embodiment of the present invention.

FIG. 2 is a cross-sectional view of the display apparatus of FIG. 1.

FIG. 3 schematically illustrates light paths of the external light Ls incident to the waveguide plate of FIG. 1 and FIG. 2.

FIG. 4 is a cross-sectional view of a display apparatus according to another embodiment of the present invention.

FIG. 5 is a cross-sectional view of a display apparatus according to further another embodiment of the present invention.

FIG. 6 is a cross-sectional view of a display apparatus according to still another embodiment of the present invention.

### DESCRIPTION OF THE EMBODIMENTS

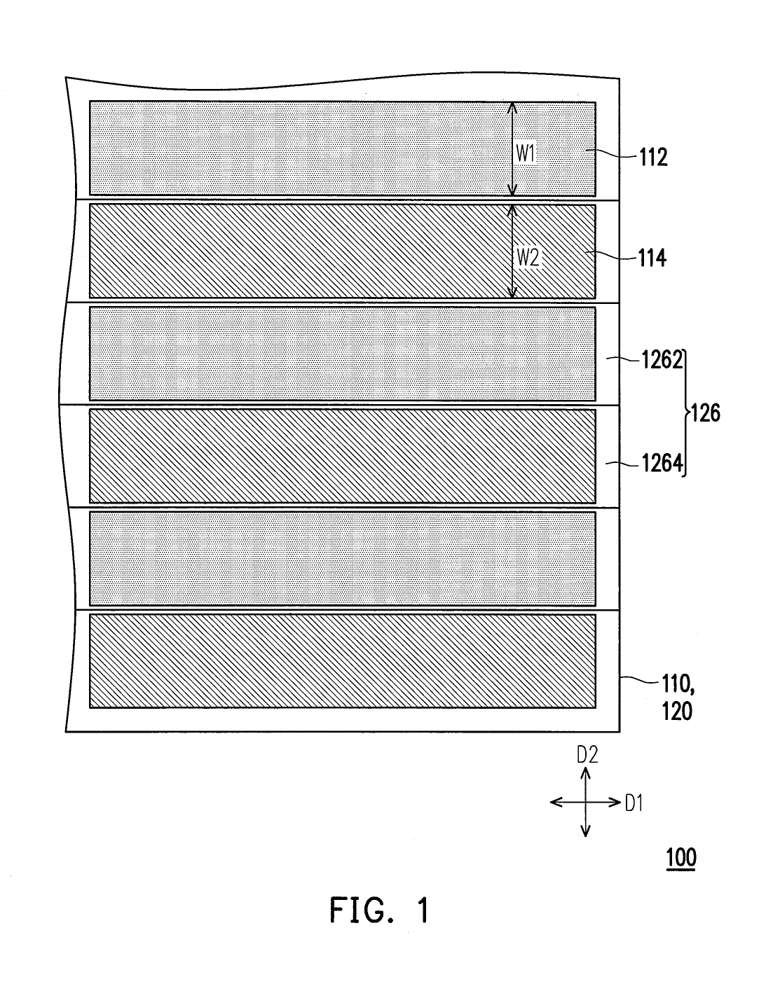

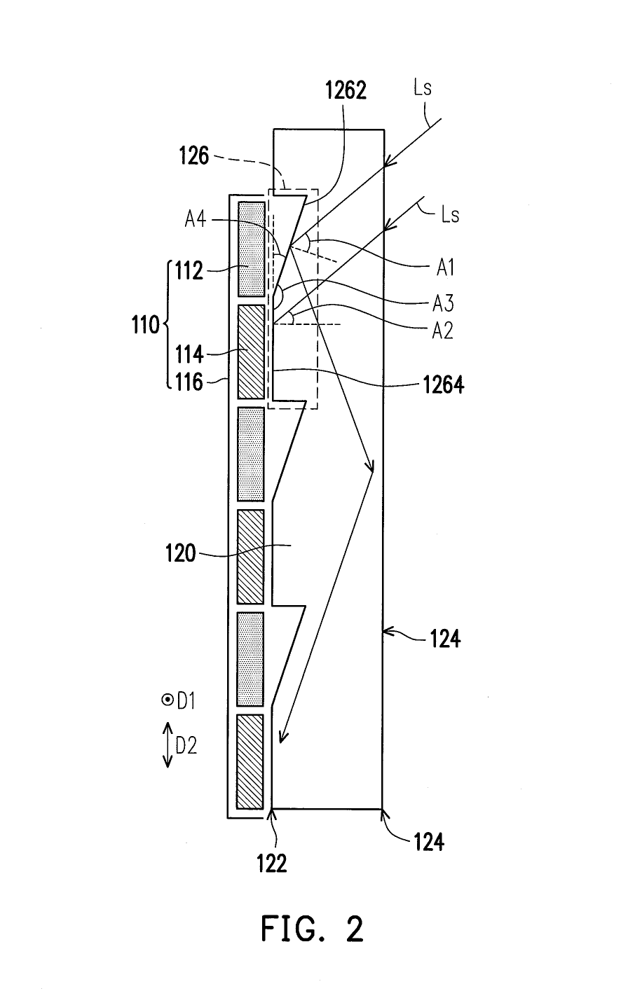

FIG. 1 is a top view of a display apparatus according to one embodiment of the present invention. FIG. 2 is a cross-sectional view of the display apparatus of FIG. 1. Referring to FIG. 1, the display apparatus 100 includes a display panel 110 and a waveguide plate 120. In FIG. 1, the display panel 110 and the waveguide plate 120 are illustrated as being overlapped with each other. As can be seen from FIG. 2, the waveguide plate 120 is disposed at one side, such as the front side, of the display panel 110.

In the present embodiment, the display panel 110 includes multiple rows of display units 112 and multiple rows of solar cell units 114. In a non-limiting example, the display unit 112 may be a light emitting diode unit. In another embodiment, the display unit 112 may be any unit that can provide image display function, for example, an electrophoretic display unit, an electro-wetting display unit, a liquid crystal display unit, an organic light emitting display unit or another display unit. The display units 112 and the solar cell units 114 are substantially parallel to a first direction D1 and are alternately arranged along a second direction D1 perpendicular to the first direction D1. That is, in the second direction D1, one row of solar cell unit 114 disposed between two adjacent display units 112, and one row of display unit 112 disposed between two adjacent solar cell units 114. As can be further seen from FIG. 2, the display panel 100 further includes a housing 116 that houses the display units 112 and the solar cell units 114. In one embodiment, the display panel 110 may further include components such as a driving circuit unit and a power supply unit. In addition, the solar cell units 114 may be electrically connected with the display units 112 to provide the display units 112 with needed power.

The display unit 112 may substantially consist of multiple light emitting diodes (not shown) arranged in the first direction D. The solar cell unit 114 may consist of multiple solar cell panels arranged in the first direction D1 or consist of a strip-shaped solar cell panel. Here, the light emitting diodes (not shown) of the display units 112 and the solar cell panels of the solar cell units 114 are all faced toward the waveguide plate 120. In other words, the light emitting surfaces of the light emitting diodes (not shown) in the display units 112 face toward the waveguide plate 120 and the light receiving surface of the solar cell panel(s) of the solar cell unit 114 also faces toward the waveguide plate 120. Therefore, the display units 112 and the solar cell units 114 are substantially coplanar.

In addition, various components in the display panel 110 may be sized depending upon the size and resolution of the display panel 110. In one embodiment, a width w1 of the display unit 112 in the second direction D2 and a width W2 of the solar cell unit 114 in the second direction D2 can be each substantially 0.5 centimeters. That is, these components of the display panel 110 substantially arranged to have a pitch of 1 centimeter along the second direction D1. However, this particular size is for the purposes of illustration only and should not be regarded as limiting.

A material of the waveguide plate 120 includes polymethylmethacrylate (PMMA). The waveguide plate 120 includes a first side 122 adjacent to the display panel 110 and a second side 124 opposite to the first side 122. The first side 122 includes a plurality of microstructures 126. Each microstructure 126 substantially includes a first structure surface 1262 and a second structure surface 1264. The first structure surface 1262 and the second structure surface 1264 of each microstructure 126 correspond to one row of display unit 112 and one row of solar cell unit 114, respectively. Therefore, the first structure surface 1262 and the second structure surface 1264 are alternately arranged in the second direction D2. In addition, the second side 124 has, for example, a flat surface.

Specifically, when the display apparatus 100 is applied in large outdoor billboards, external light Ls (e.g. solar light) irradiates downward from the top of the display apparatus 100. Therefore, when the display apparatus 100 is disposed such that the second direction D2 is perpendicular to the ground surface, an inclination of the first structure surface 1262, for example, makes a thickness of the waveguide plate 120 gradually decrease along an upward direction from the ground surface. In addition, the second structure surface 1264 is, for example, parallel to the second side 124. However, this specific construction is for the purposes of illustration only and should not be regarded as limiting.

As a result, external light Ls irradiating onto the waveguide plate 120 in a tilting direction has an incident angle A1 at the first structure surface 1262 larger than an incident angle A2 at the second structure surface 1264, which can increase the possibility of the external light Ls to be subjected to a total reflection at the first structure surface 1262. Therefore, the percentage of the external light Ls irradiating onto the display units 112 can be significantly reduced, which facilitates preventing the temperature rise of the display units 112 due to the irradiation of the external light Ls and hence prolonging the lifetime of the display units 112.

On the other hand, the external light Ls has the smaller incident angle A2 at the second structure surface 1264, making it not easy to be subjected to the total reflection, which facilitates guiding the external light Ls to the solar cell unit 114 corresponding to the second structure surface 1264. Therefore, the arrangement of the waveguide plate 120 can not only prolong the lifetime of the display units 112 but also increase the photovoltaic conversion performance of the solar cell units 114.

In the present embodiment, in order to make the incident angle A1 of the external light Ls at the first structure surface 1262 larger than the incident angle A2 at the second structure surface 1264, an angle A3 between the first structure surface 1262 and the second structure surface 1264 of each microstructure 120 is substantially less than 180 degrees. In addition, in order to achieve a required optical effect of the waveguide plate 120, the second structure surface 1264 may be a smooth surface or rough surface. That is, the present embodiment is not intended to limit the surface roughness of the second structure surface 1264 to a particular value.

When the external light Ls is the solar light, the radiation angle of the solar light varies with the change of latitude of the site. The solar zenith angle increases as the latitude becomes higher and, therefore, the incident angle A1 of the solar light Ls at the first structure surface 1262 of each microstructure 126 decreases. As such, to achieve an ideal effect, the first structure surface 1262 of each microstructure 126 may be modified depending upon the site at which the display apparatus 100 is used. For example, for the display apparatus 100 to be disposed in an area at 23 degrees latitude, an angle A4 between the first structure surface 1262 of each microstructure 126 and the second direction D2 may be approximately 5 degrees. Alternately, for the display apparatus 100 to be disposed in an area at 30 degrees latitude, the angle A4 between the first structure surface 1262 of each microstructure 126 and the second direction D2 may be approximately 7 degrees. It is to be understood that the above specific angle values are for the purposes of illustration only and therefore should not be regarded as limiting.

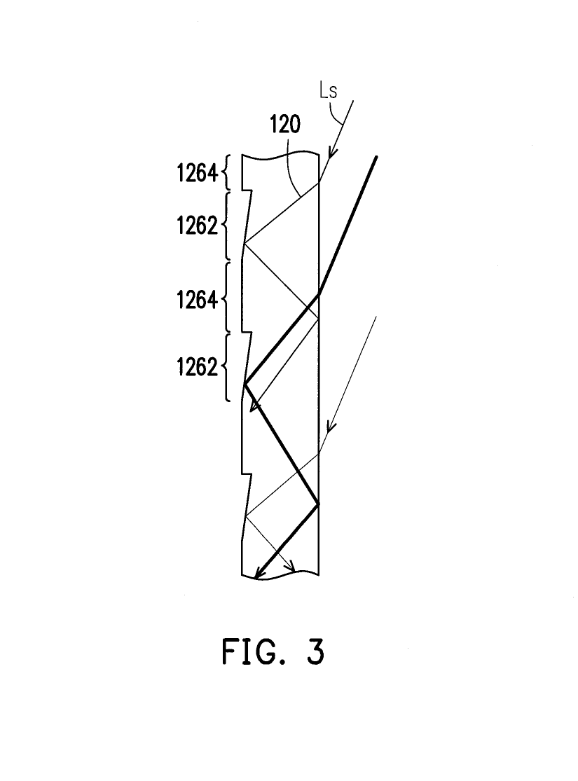

FIG. 3 illustrates light paths of the external light Ls incident on the waveguide plate of FIG. 1 and FIG. 2. As can be seen from FIG. 3, the light paths of the external light Ls irradiating onto the waveguide plate 120 in a tilting direction indicate that most of the light substantially is subjected to the total reflection at the first structure surface 1262. As such, under the acting of the waveguide plate 120, the external light Ls is not easy to irradiate onto the display units 112 corresponding to the first structure surfaces 1262, thus avoiding the temperature rise of the display units 112 due to radiation of the light. Therefore, the display apparatus of the present embodiment can have an ideal lifetime.

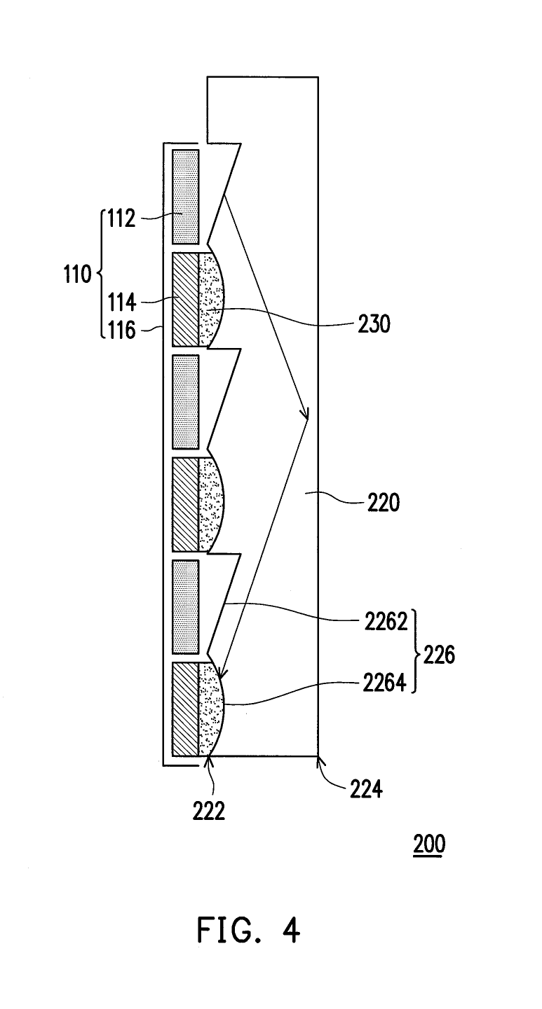

In the above embodiment, the second structure surface 1264 of each microstructure 126 is disposed in parallel with the plane of the display panel 110. However, this specific construction should not be regarded as limiting. For example, FIG. 4 is a cross-sectional view of a display apparatus according to another embodiment of the present invention. Referring to FIG. 4, the display apparatus 200 includes a display panel 110 and a waveguide plate 220. The display panel 110 is similar to the display panel 110 as described above and therefore explanation thereof is not repeated herein. The waveguide plate 220 includes a first side 222 and a second side 224. The first side 222 includes a plurality of microstructures 226, and each microstructure 226 includes a first microstructure surface 2262 and a second microstructure surface 2264. In addition, the display apparatus 200 further includes an optical adhesive 230 disposed between the second structure surface 2264 of each microstructure 226 and one corresponding row of the solar cell units 124. The refractive index of the optical adhesive 230 may be substantially equal to the refractive index of the waveguide plate 220 so as to increase the percentage of the light incident onto the solar cell units 114. In one embodiment, the optical adhesive 230 may be selectively only disposed between the solar cell units 114 and the waveguide plate 220 but not disposed between the display units 112 and the waveguide plate 220. As such, the incident light can be liable to be totally reflected at the first microstructure surface 2262 and not to irradiate onto the display units 112.

In the present embodiment, the first structure surface 2262 may be designed in the same manner as the first structure surface 1262 of the above embodiment. That is, when the display apparatus 200 is disposed to be perpendicular to the ground surface, an inclination of the first structure surface 2262, for example, makes a thickness of the waveguide plate 220 gradually decrease along an upward direction from the ground surface. The second structure surface 2264 is, for example, a curved surface. The curved surface has a concave that may be designed depending upon the desired optical effect and should not be limited to the particular concave design illustrated in FIG. 4. That is, the second structure surface 2264 may form a lens structure, such as concave lens or a convex lens. In addition, in order to achieve a specific optical effect of the waveguide plate 220, the second structure surface 2264 may be a smooth surface or rough surface. That is, the present embodiment is not intended to limit the surface roughness of the second structure surface 2264 to a particular configuration.

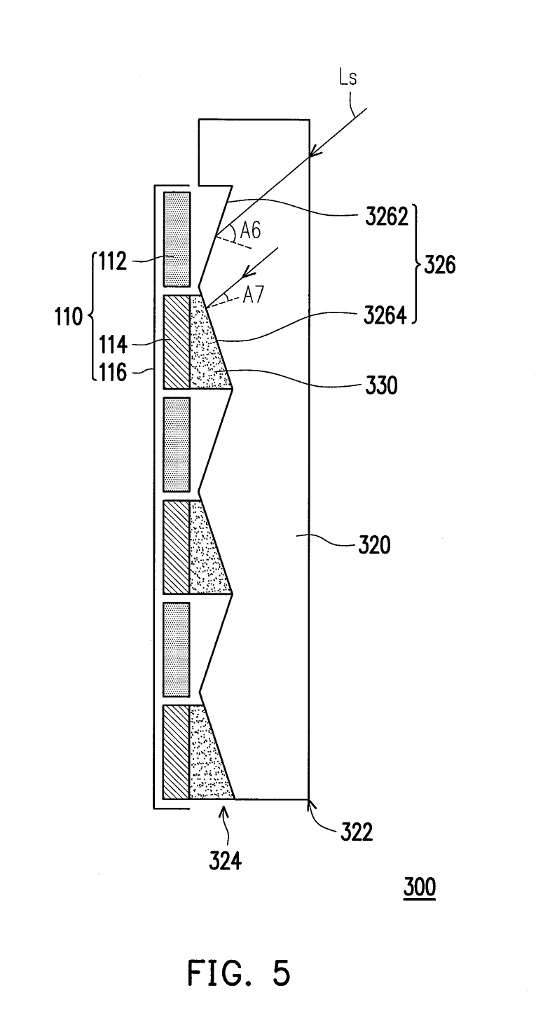

FIG. 5 is a cross-sectional view of a display apparatus according to another embodiment of the present invention. Referring to FIG. 5, the display apparatus 300 includes a display panel 110 and a waveguide plate 320. The waveguide plate 320 includes a first side 322 and a second side 324. The first side 322 includes a plurality of microstructures 326, and each microstructure 326 includes a first microstructure surface 3262 and a second microstructure surface 3264. In addition, the display apparatus 300 may further include an optical adhesive 330 disposed between the second structure surface 3264 of each microstructure 326 and one corresponding row of the solar cell units 124.

In the present embodiment, the first structure surface 3262 and the second structure surface 3264 of each microstructure 326 incline in opposite directions with respect to the boundary of the first structure surface 3262 and the second structure surface 3264. That is, when the display apparatus 300 is disposed to be perpendicular to the ground surface, the inclination of the first structure surface 3262, for example, makes a thickness of the waveguide plate 320 gradually decrease along an upward direction from the ground surface, while the inclination of the second structure surface 3264, for example, makes the thickness of the waveguide plate 320 gradually increase along the upward direction from the ground surface. In one embodiment, the first structure surface 3262 and the second structural surface 3264 of each microstructure 326 may be symmetrical with each other. It is to be understood that, in order to achieve a specific optical effect of the waveguide plate 320, the second structure surface 3264 may be a smooth surface or rough surface. That is, the present embodiment is not intended to limit the surface roughness of the second structure surface 3264 to a particular configuration.

When the display apparatus 300 is disposed to be perpendicular to the ground surface, an incident angle A6 of the external light Ls irradiating from the top of the display apparatus 300 at the first structure surface 3262 is apparently greater than an incident angle A7 at the second structure surface 3264. Therefore, the external light Ls is easier subjected to a total reflection at the first structure surface 3262 and therefore does not irradiate onto the display units 112 corresponding to the first structure surfaces 3262. In addition, the external light Ls is not easily subjected to a total reflection at the first structure surface 3264 and therefore can irradiate onto the solar units 114 corresponding to the second structure surfaces 3264. As a result, the temperature rise of the display units 112 due to irradiation of the external light Ls is not easy to occur, thus prolonging the lifetime of the display unit 112. At the same time, the solar cell units 114 may have an enhanced photovoltaic conversion performance because of the increased amount of light received.

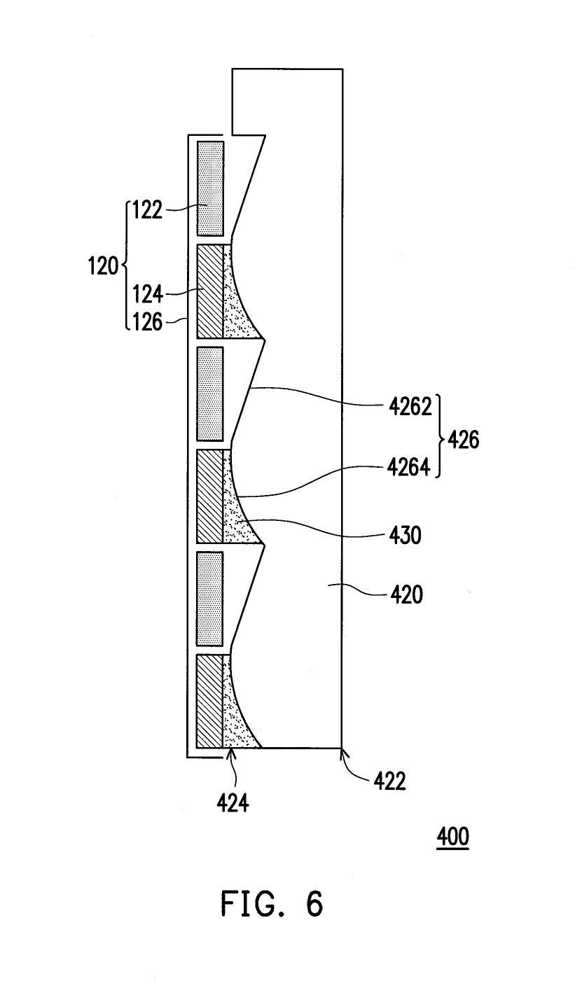

FIG. 6 is a cross-sectional view of a display apparatus according to another embodiment of the present invention. Referring to FIG. 6, the display apparatus 400 includes a display panel 110 and a waveguide plate 420. The waveguide plate 420 includes a first side 422 and a second side 424. The first side 422 includes a plurality of microstructures 426, and each microstructure 426 includes a first microstructure surface 4262 and a second microstructure surface 4264. In addition, the display apparatus 400 may further include an optical adhesive 430 disposed between the second structure surface 4264 of each microstructure 426 and one corresponding row of the solar cell units 124.

The first structure surface 4262 and the second structure surface 4264 of each microstructure 426 incline in opposite directions with respect to the boundary between the first structure surface 4262 and the second structure surface 4264 of each microstructure 426. That is, when the display apparatus 400 is disposed to be perpendicular to the ground surface, the inclination of the first structure surface 4262, for example, makes a thickness of the waveguide plate 420 gradually decrease along an upward direction from the ground surface, while the inclination of the second structure surface 4264, for example, makes the thickness of the waveguide plate 420 gradually increase along the upward direction from the ground surface. In addition, in the present embodiment, the second structure surface 4264 may be a curved surface. The curved surface has a convex that may be designed depending upon the desired optical effect and should not be limited to the particular convex design illustrated in FIG. 6. It is to be understood that, in order to achieve a specific optical effect of the waveguide plate 420, the second structure surface 4264 may be a smooth surface or rough surface. That is, the present embodiment is not intended to limit the surface roughness of the second structure surface 4264 to a particular configuration.

In summary, in embodiments of the present invention, the display apparatus includes the display panel and the waveguide plate disposed in front of the display panel. The display panel includes multiple rows of display units and multiple rows of solar cell units. One side of the waveguide plate adjacent to the display panel includes multiple microstructures. In the microstructures, the structure surfaces corresponding to the solar cell unit are designed to be an inclined surface such that the external light has an increased incident angle at this structure surfaces, thereby reducing the possibility of the external light to directly irradiate onto the display units. As a result, the lifetime of the display units is not shortened because of the component temperature rise due to the irradiation of the external light. In addition, the structure surfaces of the microstructure of the waveguide plate corresponding to the solar cell units do not cause the incident angle of the external light at this structure surfaces to be increased, thereby increasing the possibility of the external light to directly irradiate onto the solar cell units, which further enhancing the photovoltaic conversion performance of the solar cell units.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A display apparatus comprising:
a display panel comprising multiple rows of display units and multiple rows of solar cell units, the display units and the solar cell units being substantially parallel to a first direction and alternately arranged along a second direction perpendicular to the first direction; and
a waveguide plate disposed at one side of the display panel, a first side of the waveguide plate adjacent to the display panel comprising a plurality of microstructures, each microstructure substantially being configured as parallel to the first direction and comprising a first structure surface and a second structure surface, wherein the first structure surface and the second structure surface of each microstructure respectively correspond to one row of the display units and one row of the solar cell units, and when the display apparatus is disposed such that the second direction is perpendicular to a ground surface, an inclination of the first structure surface makes a thickness of the waveguide plate gradually decrease along an upward direction from the ground surface.

2. The display apparatus according to claim 1, wherein the display units comprise light emitting diode units, electrophoretic display units, electro-wetting display units, liquid crystal display units, and organic light emitting display units.

3. The display apparatus according to claim 1, wherein the display units and the solar cell units are substantially coplanar.

4. The display apparatus according to claim 1, wherein an angle between the first structure surface and the second structure surface of each microstructure is substantially less than 180 degrees.

5. The display apparatus according to claim 1, wherein the second structure surface of each microstructure is substantially parallel to a display surface of the corresponding one display unit.

6. The display apparatus according to claim 1, wherein the first structure surface and the second structure surface of each microstructure incline in opposite directions with respect to a boundary between the first structure surface and the second structure surface.

7. The display apparatus according to claim 1, wherein the first structure surface and the second structure surface of each microstructure are symmetrically configured with respect to a boundary between the first structure surface and the second structure surface.

8. The display apparatus according to claim 1, wherein the second structure surface of each microstructure is a rough surface.

9. The display apparatus according to claim 1, wherein the second structure surface of each microstructure is a curved surface.

10. The display apparatus according to claim 1, wherein the first structure surfaces and the second structure surfaces of the microstructures are alternately arranged along the second direction.

11. The display apparatus according to claim 1, wherein when the display apparatus is used at a 23 degrees latitude site, the angle between the first structure surface of each microstructure and the second direction is 5 degrees.

12. The display apparatus according to claim 1, wherein when the display apparatus is used at a 30 degrees latitude site, the angle between the first structure surface of each microstructure and the second direction is 7 degrees.

13. The display apparatus according to claim 1, further comprising an optical adhesive disposed between the second structure surface of each microstructure and one corresponding row of the solar cell units.

14. The display apparatus according to claim 13, wherein a refractive index of the optical adhesive is substantially equal to a refractive index of the waveguide plate.

15. The display apparatus according to claim 1, wherein a material of the waveguide plate comprises polymethylmethacrylate.

16. The display apparatus according to claim 1, wherein a second side of the waveguide plate comprises a flat surface, and the first side and the second side are opposite to each other.
